(19) United States
(12) Patent Application Publication
(10) Pub. No.: US 2021/0202772 A1
(43) Pub. Date: Jul. 1, 2021

(54) FLEXIBLE SOLAR BATTERY COMPONENT

(71) Applicant: MIASOLÉ EQUIPMENT INTEGRATION (FUJIAN) CO., LTD., FUJIAN (CN)

(72) Inventors: WEI LONG, FUJIAN (CN); JIHONG XIAO, FUJIAN (CN); HU JIANG, FUJIAN (CN); ZHONGYAN LIAN, FUJIAN (CN); YI SHU, FUJIAN (CN); MINGHAO QU, FUJIAN (CN)

(21) Appl. No.: 16/075,011

(22) PCT Filed: Jun. 25, 2018
(86) PCT No.: PCT/CN2018/092619

§ 371 Date: Aug. 2, 2018

(30) Foreign Application Priority Data
Dec. 15, 2017 (CN) 201721757407.4

(51) Int. Cl. H01L 31/05; H01L 31/0475; H01L 31/0224

(52) U.S. Cl. CPC H01L 31/0508; H01L 31/022466; H01L 31/0512; H01L 31/0475

(57) ABSTRACT

The present disclosure provides a flexible solar battery component, which includes a plurality of cell chips. A conductive lead wire is provided at a top surface of each cell chip. A contact electrode is provided at an edge of a side of the top surface of each cell chip. A metal base is provided at a bottom surface of each cell chip. One end of the conductive lead wire of each cell chip is coupled with the contact electrode of each cell chip, and the other end of the conductive lead wire of each cell chip is in an electrical connection with the metal base of each cell chip. In every two adjacent cell chips, the metal base of one of the two adjacent cell chips is pressure-welded to the contact electrode of the other of the two adjacent cell chips.

### CROSS-REFERENCE TO RELATED APPLICATION

This application is the U.S. national phase of PCT Application No. PCT/CN2018/092619 filed on Jun. 25, 2018, which is based on and claims priority of Chinese Patent Application No. 201721757407.4, filed on Dec. 15, 2017, the disclosures of which are incorporated in their entirety by reference herein.

### TECHNICAL FIELD

The present disclosure relates to the field of solar cell technology, and in particular to a flexible solar battery component.

### BACKGROUND

Currently, in the process of manufacturing flexible photovoltaic modules, it is needed to connect individual cell chips in a series, and then forming a complete solar cell by laminating the cell chips between a front plate and a back plate. An interconnectivity of the cell chips directly affects conversion efficiency of solar cell.

### SUMMARY

The present disclosure provides a flexible solar battery component, which includes a plurality of cell chips. A conductive lead wire is provided at a top surface of each cell chip. A contact electrode is provided at an edge of a side of the top surface of each cell chip. A metal base is provided at a bottom surface of each cell chip. One end of the conductive lead wire of each cell chip is coupled with the contact electrode of each cell chip, and the other end of the conductive lead wire of each cell chip is in an electrical connection with the metal base of each cell chip. In every two adjacent cell chips, the metal base of one of the two adjacent cell chips is pressure-welded to the contact electrode of the other of the two adjacent cell chips.

In the above flexible solar battery component, optionally, the conductive lead wire of each cell chip is a metal lead wire.

In the above flexible solar battery component, optionally, the contact electrode of each cell chip is made of one or more of gold, silver, copper, aluminum, nickel, titanium, vanadium, chromium, molybdenum, palladium, platinum and zin.

In the above flexible solar battery component, optionally, the conductive lead wire of each cell chip is attached to the top surface of each cell chip through a conductive adhesive tape.

In the above flexible solar battery component, optionally, the contact electrode of each cell chip is printed at the edge of the side of the top surface of each cell chip by screen printing or inkjet printing.

In the above flexible solar battery component, optionally, the conductive lead wire of each cell chip has a width in in a range of from 10 um to 100 um and a height in a range of from 10 um to 50 um.

In the above flexible solar battery component, optionally, there is a plurality of conductive lead wires at each cell chip.

In the above flexible solar battery component, optionally, the conductive lead wires at each cell chip are distributed in form of strips or a grid.

In the above flexible solar battery component, optionally, the contact electrode of each cell chip is rectangular; a length of the contact electrode of each cell chip is equal to a length of the each cell chip.

In the above flexible solar battery component, optionally, a shape of the contact electrode includes a plurality of ellipses sequentially connected.

In the above flexible solar battery component, optionally, the other end of the conductive lead wire of each cell chip is in an electrical connection with the metal base of each cell chip by means of a via-hole.

In the above flexible solar battery component, optionally, a width of the contact electrode of each cell chip is equal to a difference of a width of each cell chip and a length of the conductive lead wire of each cell chip.

In the above flexible solar battery component, optionally, the conductive lead wire of each cell chip is attached to the top surface of each cell chip by a transparent conductive adhesive tape.

In the above flexible solar battery component, optionally, the metal base of each cell chip covers an entire bottom surface of each cell chip.

In the above flexible solar battery component, optionally, the conductive lead wire of each cell chip has the same sizes as the transparent conductive adhesive tape.

In the above flexible solar battery component, optionally, the conductive lead wire of each cell chip and the contact electrode of each cell chip are directly formed at the top surface of each cell chip.

In the above flexible solar battery component, optionally, the conductive lead wire of each cell chip is made of one or more of gold, silver, copper, aluminum, nickel, titanium, vanadium, chromium, molybdenum, palladium, platinum and zin.

In the above flexible solar battery component, optionally, the contact electrode of each cell chip is attached to the edge of the side of the top surface of each cell chip through a conductive adhesive tape.

In the above flexible solar battery component, optionally, the contact electrode of each cell chip is attached to the edge of the side of the top surface of each cell chip through a transparent conductive adhesive tape.

In the above flexible solar battery component, optionally, the contact electrode of each cell chip has the same sizes as the transparent conductive adhesive tape.

### BRIEF DESCRIPTION OF THE DRAWINGS

FIG. 1 is a schematic view of a monolithic integrated cell chip in the related art;

FIG. 2 is a schematic view of interconnection of a pre-divided cell chip in the related art;

FIG. 3 is a schematic view of a flexible solar battery component according to an embodiment of the present disclosure;

FIG. 4 is a schematic view of a cell chip of a flexible solar battery component according to an embodiment of the present disclosure; and

FIG. 5 is a schematic view of another cell chip of a flexible solar battery component according to an embodiment of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise indicated. The following description of exemplary embodiments is merely used to illustrate the present disclosure and is not to be construed as limiting the present disclosure.

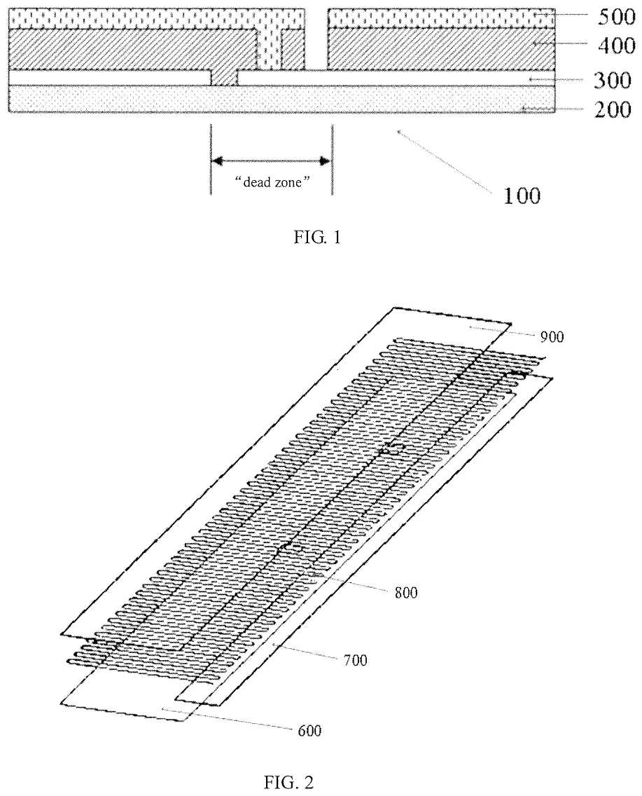

There are two interconnection techniques in the related art. One cell chip interconnection technique is monolithic integration. As shown in FIG. 1, the cell chip 100 includes a metal base 200, a first electrode 300, an absorption layer 400 and a second electrode 500 which are sequentially arranged from bottom to up. In manufacture process, the first electrode 300 is prepared at the metal base 200, and a first groove is engraved in the first electrode 300; then, the absorption layer 400 is prepared at the first electrode 300 and a second groove is engraved in the absorption layer 400; then the second electrode 500 is prepared at the absorption layer 400 and a third groove is engraved in the second electrode 500. A protrusion of the absorption layer 400 is snapped into the first groove, and a protrusion of the second electrode 500 is snapped into the second groove. In other words, in the manufacturing process, the interconnection of cell chips is realized by a group of three grooves (laser engraved grooves or mechanically engraved grooves), and a distance (i.e., pitch width) between the grooves in each group determines final output current voltage. Another cell chip interconnection technique is to use metal wire mesh and auxiliary materials to interconnect pre-divided cell chips. As shown in FIG. 2, a pre-divided cell chip 600, a first transparent polymer material 700, a metal wire mesh 800 and a second transparent polymer material 900 are sequentially arranged from bottom to up. Adjacent pre-divided cell chips 600 are interconnected by the first transparent polymer material 700. The metal wire mesh 800 is used to interconnection within the pre-divided cell chip 600. An area of the cell chip and serial parallel combination of the cell chips determine the final output current and voltage.

The above two methods have the following problems.

1. In the monolithic integration interconnection technique, a region in each group of three grooves is a “dead zone” that has no contribution to power generation. As shown in FIG. 1, an area occupied by the “dead zone” is determined by spacing and quantity of the grooves. Since the “dead zone” does not generate power, the total conversion efficiency of the component is thus reduced.

2. The monolithic integration interconnection technique utilizes most of a coating area, but it is difficult to control uniformity of large-area coating and edge randomness is high, the fixed pitch width easily causes a mismatch in the output current in actual production and current limiting effect in series may affect conversion efficiency.

3. The pre-divided cell chip may partially improve the negative impact caused by non-uniformity of the large-area coating, but the metal wire mesh and auxiliary materials (which are usually transparent polymer materials) required for interconnection have to be produced separately, and sizes (mainly the width) after combination limit sizes of the flexible solar battery component, and thus flexibility of production is greatly reduced. Weaving of the metal wire mesh and the combination of auxiliary materials require special equipment, which increases complexity of production line equipment, process, material and quality control.

4. A cross-section of the basic unit of the metal wire mesh, i.e., the metal wire, is nearly circular, thus the metal wire has a small contact area with the flexible solar battery component and there is large contact resistance, resulting in large resistance when connected in series and more loss of output power. In addition, during lamination, the wire is subjected to larger lamination pressure and then there is a high pressure at contact between the wire and the surface of the flexible solar battery component, which easily causes cracking and collapsing of membranes, results in internal short circuit, loss of output power and other risks such as hot spots and insulation failure. When the metal wire has intersections, the intersections may cause more damage to the surface of flexible solar battery component.

5. The auxiliary materials (including transparent polymer materials and adhesive glue) for the metal wire mesh may cause some loss of current due to their own transmittance. In addition, when used outdoors for a long time, the auxiliary materials easily produce turbidity, yellowing and other aging phenomena due to ultraviolet radiation, and then the transmittance of the auxiliary materials is further deteriorated. Moreover, when used outdoors for a long time, under the effect of periodic temperature change, alternating hot and cold will cause significant stress as a thermal expansion coefficient of the auxiliary materials is greater than a thermal expansion coefficient of the flexible solar battery component, which easily cause separation between the auxiliary materials and even separation between inner membranes of the flexible solar battery component, resulting in poor appearance and attenuation of electrical performance.

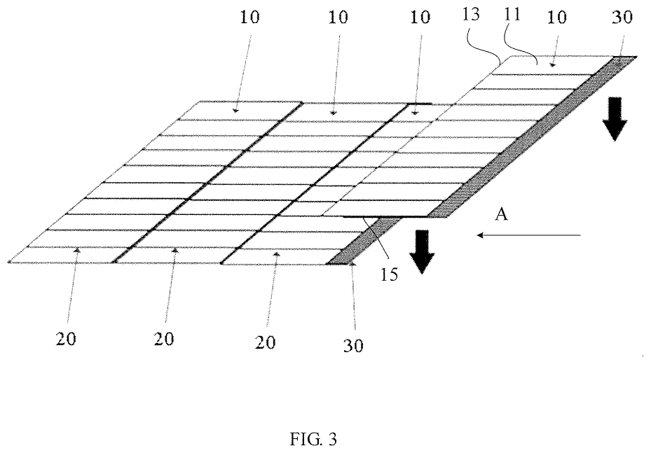

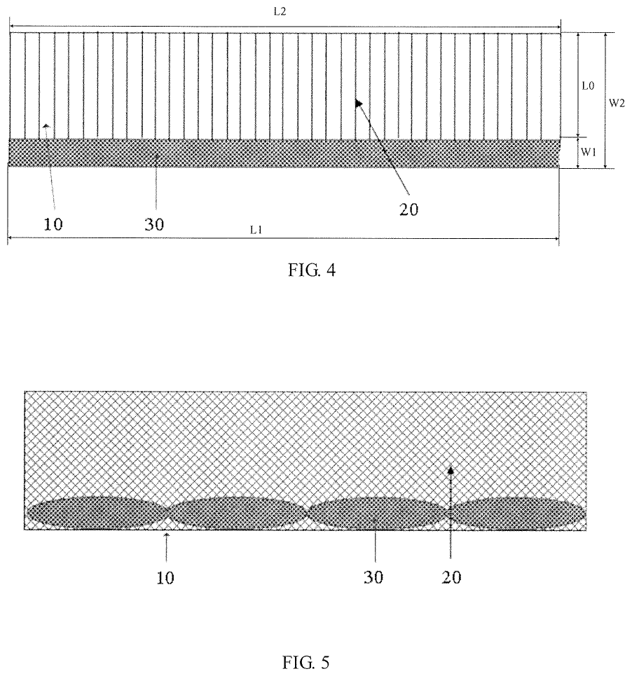

In order to solve the above technical problems, one embodiment of the present disclosure provides a flexible solar battery component. As shown in FIG. 3 to FIG. 5, the flexible solar battery component in one embodiment of the present disclosure includes a plurality of cell chips 10.

A conductive lead wire 20 is provided at a top surface 11 of the cell chip 10. A contact electrode 30 is provided at an edge of a side of the top surface 11 of the cell chip 10. A metal base 15 is provided at a bottom surface of the cell chip 10. One end of the conductive lead wire 20 is coupled with the contact electrode 30, and the other end of the conductive lead wire 20 is in an electrical connection with the metal base 15. In adjacent two cell chips 10, the metal base 15 of one cell chip 10 is pressure-welded to the contact electrode 30 of the other cell chip 10. In one embodiment, the conductive lead wire 20 may be in an electrical connection with the metal base 15 by means of a via-hole.

In the flexible solar battery component of one embodiment of the present disclosure, the lead wire 20 and the contact electrode 30 are directly prepared at the cell chip 10 with no dead zone, and a light receiving area is increased, thereby improving conversion efficiency. Further, since it is not necessary to arrange materials such as metal wire mesh and adhesive glue in advance, damage of a surface and inner membranes of the flexible solar battery component caused by the pressure of the metal wire mesh is avoided, thereby improving reliability. Meanwhile, the risk of failure and stress of auxiliary materials such as adhesives due to UV aging and temperature cycling can be eliminated, and this allows the flexible solar battery component to be used outdoors for a long time, prolongs the service life and greatly reduces complexity of production line equipment, process, material and quality control.

In addition, in case of interconnection, it only needs to sequentially arrange the cell chips 10 in such a manner that a bottom surface of a second cell chip 10 is pressure-welded to a contact electrode 30 at a top surface of a first cell chip 10, a bottom surface of a third cell chip 10 is pressure-welded to a contact electrode 30 at a top surface of the second cell chip 10 and so on, thus operations are simple and production efficiency can be improved. Since the bottom surface of the cell chip 10 is the metal base 15, interconnection of the cell chips 10 may be realized simply by pressure-welding the bottom surface of the cell chip 10 to the contact electrode 30 of the adjacent cell chip 10.

Specifically, the conductive lead wire 20 may be a metal lead wire. Optionally, the conductive lead wire 20 may be made of one or several of gold, silver, copper, aluminum, nickel, titanium, vanadium, chromium, molybdenum, palladium, platinum and zin. In order to reduce cost, the conductive lead wire 20 may be made of copper or other low cost metals.

Specifically, the contact electrode 30 may be made of one or several of gold, silver, copper, aluminum, nickel, titanium, vanadium, chromium, molybdenum, palladium, platinum and zin. In order to reduce cost, the contact electrode 30 may be made of copper or other low cost metals.

In one embodiment, the conductive lead wire 20 may be attached to the cell chip 10 by a conductive adhesive tape (such as a transparent conductive adhesive tape). Optionally, in other embodiments, the conductive lead wire 20 may be fabricated on the cell chip 10 by means of magnetron sputtering with a mask, vacuum evaporation coating with a mask, screen printing, inkjet printing or photo-induced electroplating, which may be selected by those skilled in the art according to needs. In one embodiment, when the conductive lead wire 20 is attached to the cell chip 10 by a transparent conductive adhesive tape, the conductive lead wire 20 may have the same sizes as the transparent conductive adhesive tape, thus the transparent conductive adhesive tape substantially coincides with the conductive lead wire 20 in the drawings.

Further, the contact electrode 30 may be fabricated on the cell chip 10 by means of a conductive adhesive tape (such as a transparent conductive adhesive tape), magnetron sputtering with a mask, vacuum evaporation coating with a mask, screen printing, inkjet printing or photo-induced electroplating. In one embodiment, when the contact electrode 30 is attached to the cell chip 10 by the transparent conductive adhesive tape, the contact electrode 30 may have the same sizes as the transparent conductive adhesive tape, thus the transparent conductive adhesive tape substantially coincides with the contact electrode 30 in the drawings.

As can be understood by those skilled in the art that there may be several conductive lead wires 20, and these conductive lead wires 20 may be distributed in any shapes which may be designed by those skilled in the art according to actual needs. Further, the conductive lead wire 20 has a width in a range of from 10 um to 100 um and a height in a range of from 10 um to 50 um. A length of the conductive lead wire 20 may be designed according to specific sizes of the cell chip 10 in such a manner that the conductive lead wire 20 can occupy an entire portion for arranging the conductive lead wire 20 at the top surface of the cell chip 10. Here, the height of the conductive lead wire 20 refers to a height of the conductive lead wire 20 with respect to the top surface 11 of the cell chip 10.

FIG. 3 shows that the conductive lead wire 20 is strip-shaped. As can be seen from FIG. 3, one end of the conductive lead wire 20 is connected with the contact electrode 30, and the other end of the conductive lead wire 20 extends in a direction (which is indicated with an arrow A shown in FIG. 3) away from the contact electrode 30, and extends to a first long side 13 of the cell chip 10. The contact electrode 30 is a rectangular. A length L1 of the contact electrode 30 is equal to a length L2 of the cell chip 10. A width W1 of the contact electrode 30 is determined according to a width W2 of the cell chip 10 and a length L0 of the conductive lead wire 20. In one embodiment, the width W1 of the contact electrode 30 is equal to a difference of the width W2 of the cell chip 10 and the length L0 of the conductive lead wire 20.

FIG. 5 shows that the conductive lead wires 20 have a grid-like shape. As can be seen from FIG. 5, several conductive lead wires 20 cross each other to form a grid. A shape of the contact electrode 30 includes several ellipses sequentially connected. On one hand, the elliptical contact electrode 30 may save materials; on other hand, the elliptical contact electrode 30 can provide a better electricity collecting effect as compared with a rectangular contact electrode.

Of course, the conductive lead wire 20 and the contact electrode 30 may be arranged in any desired shapes, so as to provide different cell chips 10 according to different requirements of different users, thereby improving versatility of the cell chips 10.

In order to further save materials, in an optional embodiment, the conductive lead wire 20 may be strip-shaped, and the contact electrode 30 may be elliptical.

In another optional embodiment, the conductive lead wires 20 may be oblique stripes, and the contact electrode 30 may have a shape of a diamond.

Finally, it should be noted, sizes (cell length, cell width) of the flexible solar battery component may be optimized based on designed current and voltage. The voltage of the flexible solar battery component is equal to the voltage of the monolithic cell chip 10 multiplied by the number of cell chips 10. The current of the flexible solar battery component is directly proportional to an area of the top surface of the flexible solar battery component that is not blocked by the metal lead wires and the contact electrode 30, and is approximately equal to the length of the cell multiplied by a difference between the width of the flexible solar battery component and the width of the contact electrode 30.

The width of the contact electrode 30 may be optimized based on electrical conductivity of the base at the bottom surface of the flexible solar battery component. The higher the electrical conductivity of the base is, the narrower the width of the contact electrode 30 is. A density of the conductive lead wires 20 (i.e., number of the conductive lead wires 20 per centimeter) may be optimized based on square resistance of the top surface of the flexible solar battery component. The lower the square resistance of a front surface of the cell is, the lower the density of the conductive lead wires 20 is. Those can be flexibly set by those skilled in the art according to actual needs.

Based on the embodiments shown in the drawings, the structure, characteristics and effect of the present disclosure are explained in detail. The above are merely the optional embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

What is claimed is:

1. A flexible solar battery component comprising:
a plurality of cell chips;
wherein a conductive lead wire is provided at a top surface of each cell chip; a contact electrode is provided at an edge of a side of the top surface of each cell chip; a metal base is provided at a bottom surface of each cell chip;
wherein one end of the conductive lead wire of each cell chip is coupled with the contact electrode of each cell chip, and the other end of the conductive lead wire of each cell chip is in electrical connection with the metal base of each cell chip; and
wherein in every two adjacent cell chips, the metal base of one of the two adjacent cell chips is pressure-welded to the contact electrode of the other of the two adjacent cell chips.

2. The flexible solar battery component of claim 1, wherein the conductive lead wire of each cell chip is a metal lead wire.

3. The flexible solar battery component of claim 1, wherein the contact electrode of each cell chip is made of one or more of gold, silver, copper, aluminum, nickel, titanium, vanadium, chromium, molybdenum, palladium, platinum and zin.

4. The flexible solar battery component of claim 1, wherein the conductive lead wire of each cell chip is attached to the top surface of each cell chip through a conductive adhesive tape.

5. The flexible solar battery component of claim 1, wherein the contact electrode of each cell chip is printed at the edge of the side of the top surface of each cell chip by screen printing or inkjet printing.

6. The flexible solar battery component of claim 1, wherein the conductive lead wire of each cell chip has a width a range of from 10 um to 100 um and a height in a range of from 10 um to 50 um.

7. The flexible solar battery component of claim 1, wherein there is a plurality of conductive lead wires at each cell chip.

8. The flexible solar battery component of claim 7, wherein the conductive lead wires at each cell chip are distributed in form of strips or a grid.

9. The flexible solar battery component of claim 1, wherein the contact electrode of each cell chip is rectangular; a length of the contact electrode of each cell chip is equal to a length of the each cell chip.

10. The flexible solar battery component of claim 1, wherein a shape of the contact electrode includes a plurality of ellipses sequentially connected.

11. The flexible solar battery component of claim 1, wherein the other end of the conductive lead wire of each cell chip is in an electrical connection with the metal base of each cell chip by means of a via-hole.

12. The flexible solar battery component of claim 1, wherein a width of the contact electrode of each cell chip is equal to a difference of a width of each cell chip and a length of the conductive lead wire of each cell chip.

13. The flexible solar battery component of claim 1, wherein the conductive lead wire of each cell chip is attached to the top surface of each cell chip by a transparent conductive adhesive tape.

14. The flexible solar battery component of claim 1, wherein the metal base of each cell chip covers an entire bottom surface of each cell chip.

15. The flexible solar battery component of claim 13, wherein the conductive lead wire of each cell chip and the contact electrode of each cell chip are directly formed at the top surface of each cell chip.

16. The flexible solar battery component of claim 13, wherein the conductive lead wire of each cell chip and the contact electrode of each cell chip are directly formed at the top surface of each cell chip.

17. The flexible solar battery component of claim 1, wherein the conductive lead wire of each cell chip is made of one or more of gold, silver, copper, aluminum, nickel, titanium, vanadium chromium, molybdenum, palladium, platinum and zin.

18. The flexible solar battery component of claim 1, wherein the contact electrode of each cell chip is attached to the edge of the side of the top surface of each cell chip through a conductive adhesive tape.

19. The flexible solar battery component of claim 1, wherein the contact electrode of each cell chip is attached to the edge of the side of the top surface of each cell chip through a transparent conductive adhesive tape.

20. The flexible solar battery component of claim 19, wherein the contact electrode of each cell chip has the same sizes as the transparent conductive adhesive tape.
